(19) United States
(12) Patent Application Publication
(10) Pub. No.: US 2023/0223913 A1
(43) Pub. Date: Jul. 13, 2023

(54) BAW RESONANCE DEVICE, FILTER DEVICE AND RF FRONT-END DEVICE

(71) Applicant: SHENZHEN SUNWAY COMMUNICATION CO., LTD., Shenzhen, Guangdong (CN)

(72) Inventors: Chengcheng YU, Shenzhen (CN); Yanjie CAO, Shenzhen (CN); Wei WANG, Shenzhen (CN)

(73) Assignee: SHENZHEN SUNWAY COMMUNICATION CO., LTD., Shenzhen, Guangdong (CN)

(21) Appl. No.: 16/969,409

(22) PCT Filed: Jun. 11, 2020
(86) PCT No.: PCT/CN2020/095515

§ 371 Date: Apr. 3, 2023

(30) Foreign Application Priority Data
May 13, 2020 (CN) 202010400671.2

(51) Int. Cl. H03H 9/02; H03H 9/17; H03H 9/56; H03H 9/70

(52) U.S. Cl. CPC H03H 9/02102; H03H 9/17; H03H 9/173; H03H 9/568; H03H 9/703

(57) ABSTRACT

A BAW resonance device, a filter device and an RF front-end device are provided. The BAW resonance device comprises a first passive part including a first substrate and a first heat-dissipation layer located over the first substrate; a first active part including a first piezoelectric layer, a first electrode layer and a second electrode layer, wherein the first piezoelectric layer is located over the first passive part and has a first side and a second side opposite to the first side, the first passive part is located on the first side, the first electrode layer is also located on the first side and is disposed between the first passive part and the first piezoelectric layer, and the second electrode layer is located on the second side; and a first cavity located on the first side and disposed between the first passive part and the first piezoelectric layer, wherein at least one part of the first electrode layer is located on or in the first cavity. The first heat-dissipation layer can improve or flexibly adjust the heat-dissipation performance of the SAW resonance device.

### TECHNICAL FIELD

The invention relates to the technical field of semiconductors, in particular to a BAW resonance device, a filter device and an RF front-end device.

### DESCRIPTION OF RELATED ART

The radio frequency (RF) front-end chip of wireless communication equipment includes a power amplifier, a low-noise amplifier, an antenna switch, an RF filter, a multiplexer, and the like, wherein the RF filter is a surface acoustic wave (SAW) filter, a bulk acoustic wave (BAW) filter, a micro-electro-mechanical system (MEMS) filter, an integrated passive devices (IPD) filter, or the like.

SAW resonators and BAW resonators have a high quality factor value (Q value) and are used to manufacture RF filters with a low insertion loss and a high out-of-band rejection, that is, the SAW filters and the BAW filters are mainstream RF filters applied to wireless communication equipment such as mobile phones and base stations, at present. Wherein, Q value refers to the quality factor value of the resonators and is defined as a value obtained by dividing the center frequency by 3 dB bandwidth of the resonators. The operating frequency of the SAW filters is generally from 0.4 GHz to 2.7 GHz, and the operating frequency of the BAW filters is generally from 0.7 GHz to 7 GHz.

The BAW resonators have better performance than the SAW resonators. However, on account of the complicated process steps, the manufacturing cost of the BAW resonators is higher than that of the SAW resonators. The gradual evolution of the wireless communication technology leads to the usage of more and more frequency bands, and the application of frequency band superposition technologies, such as the carrier aggregation technology, results in severer and severer mutual interference between different wireless frequency bands. High-performance BAW technologies can solve the problem of mutual interference between different frequency bands. Along with the rise of 5G, higher communication frequency bands have been introduced into wireless mobile networks, and the BAW technique is the unique technique that can fulfill high-frequency filtering at present.

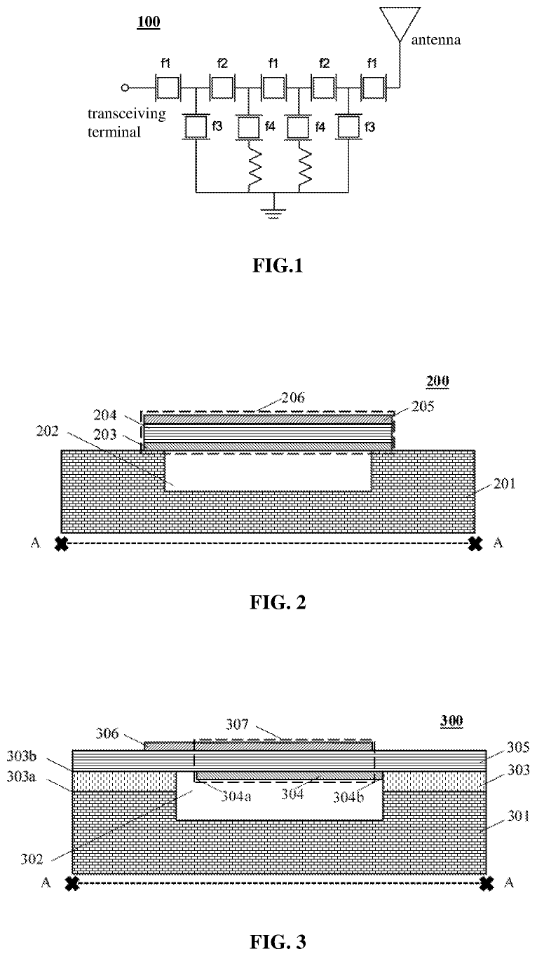

FIG. 1 illustrates a BAW filter 100 which includes a ladder circuit formed by multiple BAW resonators, wherein f1, f2, f3 and f4 respectively represent four different frequencies. In each BAW resonator, metals on two sides of a piezoelectric layer of the resonator alternately generate positive and negative voltages through which the piezoelectric layer generates acoustic waves, and the acoustic waves in the resonator propagate vertically. To form resonance, it is necessary to totally reflect the acoustic waves on the upper surface of an upper metal electrode and the lower surface of a lower metal electrode to generate standing acoustic waves. The precondition of acoustic wave reflection is that the acoustic impedance of the areas in contact with the upper surface of the upper metal electrode and the lower surface of the lower metal electrode should drastically differ from the acoustic impedance of the metal electrodes.

Film bulk acoustic wave resonators (FBARs) are BAW resonators that are able to restrain acoustic energy inside the devices, wherein air exits above the resonance region of the resonators, a cavity is formed below the resonance region of the resonators, and on account of the large difference in acoustic impedance between air and metal electrodes, acoustic waves can be totally reflected on the upper surface of the upper metal electrode and the lower surface of the lower metal electrode to generate standing waves.

FIG. 2 illustrates an FBAR 200 which comprises a substrate 201 having an upper surface formed with a cavity 202, an electrode layer 203 located over the cavity 202, a piezoelectric layer 204 located on the electrode layer 203, and an electrode layer 205 located on the piezoelectric layer 204, wherein an overlap region of the electrode layer 203 and the electrode layer 205 is a resonance region 206 which overlaps with the substrate 201. It should be noted that because air exists both above and below the resonance region, heat generated in the resonance region is typically transmitted into the substrate from the left and right sides of the resonance region and is then dissipated via the substrate, which means that the heat-dissipation capacity of the FBAR depends on the heat-dissipation capacity of the substrate, so that there remains limited room to improve or adjust the heat-dissipation capacity of the FBAR.

### BRIEF SUMMARY OF THE INVENTION

### Technical Issue

The technical issue to be settled by the invention is to provide a BAW resonance device comprising a heat-dissipation layer, which is located on a substrate or an intermediate layer and can improve or flexibly adjust the heat-dissipation performance of the BAW resonance device (for example, the heat-dissipation layer can increase the Q value of the BAW resonance device and compensate for the heat-dissipation performance of the BAW resonance device).

### SOLUTION TO THE ISSUE

### Technical Solution

To settle the above technical issue, an embodiment of the invention provides a BAW resonance device which comprises a first passive part, a first active part and a first cavity, wherein the first passive part comprises a first substrate and a first heat-dissipation layer located over the first substrate; the first active part comprises a first piezoelectric layer, a first electrode layer and a second electrode layer, wherein the first piezoelectric layer is located over the first passive part and has a first side and a second side opposite to the first side, the first passive part is located on the first side, the first electrode layer is also located on the first side and is disposed between the first passive part and the first piezoelectric layer, and the second electrode layer is located on the second side; and the first cavity is located on the first side and is disposed between the first passive part and the first piezoelectric layer, and at least one part of the first electrode layer is located on or in the first cavity.

In some embodiments, the first heat-dissipation layer is made of, but not limited to, at least one of the following materials: aluminum nitride, silicon carbide and diamond. In some embodiments, the thickness of the first heat-dissipation layer is, but not limited to, 0.1 μm-5 μm.

In some embodiments, the first cavity is inlaid in the first passive part and is located between the first substrate and the first piezoelectric layer, and the first heat-dissipation layer is located on two sides of the first cavity.

In some embodiments, the first cavity is inlaid in the first passive part and is located between the first heat-dissipation layer and the first piezoelectric layer, and the first heat-dissipation layer is located on two sides of the first cavity.

In some embodiments, the first electrode layer is located in the first cavity, and the first piezoelectric layer is located on the first electrode layer.

In some embodiments, the first heat-dissipation layer has a first groove; the first electrode layer has a first end and a second end opposite to the first end, the first end is located in the first cavity, and the second end is located in the first groove; and the first piezoelectric layer is located on the first electrode layer.

In some embodiments, the first cavity is inlaid in the first passive part and is located between the first substrate and the first electrode layer, and the first heat-dissipation layer is located on two sides of the first cavity.

In some embodiments, the first cavity is inlaid in the first passive part and is located between the first heat-dissipation layer and the first electrode layer, and the first heat-dissipation layer is located on two sides of the first cavity.

In some embodiments, the first electrode layer is located on the first cavity and is covered with the first piezoelectric layer. In some embodiments, the first piezoelectric layer comprises a first protruding part located over the first electrode layer, and the second electrode layer is located on the first piezoelectric layer and comprises a second protruding part located over the first protruding part. In some embodiments, the first protruding part is of at least one of the following shapes: trapezoidal shape and rectangular shape; and the second protruding part is of at least one of the following shapes: trapezoidal shape and rectangular shape.

In some embodiments, the first cavity is located between the first heat-dissipation layer and the first piezoelectric layer and is disposed on the first heat-dissipation layer.

In some embodiments, the first electrode layer is located on the first heat-dissipation layer and comprises a third protruding part located on the first cavity, the first piezoelectric layer covers the first cavity and comprises a fourth protruding part located over the third protruding part, and the second electrode layer is located on the first piezoelectric layer and comprises a fifth protruding part located over the fourth protruding part. In some embodiments, the third protruding part is of at least one of the following shapes: trapezoidal shape, arch shape and rectangular shape; the fourth protruding part is of at least one of the following shapes: trapezoidal shape, arch shape and rectangular shape; and the fifth protruding part is of at least one of the following shapes: trapezoidal shape, arch shape and rectangular shape.

In some embodiments, the first passive part further comprises a first intermediate layer located between the first substrate and the first heat-dissipation layer and disposed on the first substrate, and the first heat-dissipation layer is located on the first intermediate layer.

In some embodiments, the first intermediate layer is made of, but not limited to, at least one of the following materials: polymer, insulating dielectric and polysilicon. In some embodiments, the thickness of the first intermediate layer is, but not limited to, 0.1 μm-10 μm.

In some embodiments, the first cavity is inlaid in the first passive part and is located between the first intermediate layer and the first piezoelectric layer, and the first heat-dissipation layer is located on two sides of the first cavity.

In some embodiments, the first electrode layer is located in the first cavity, and the first piezoelectric layer is located on the first electrode layer.

In some embodiments, the first heat-dissipation layer has a second groove; the first electrode layer has a third end and a fourth end opposite to the third end, the third end is located in the first cavity, and the fourth end is located in the second groove; and the first piezoelectric layer is located on the first electrode layer.

In some embodiments, the first cavity is inlaid in the first passive part and is located between the first intermediate layer and the first electrode layer, and the first heat-dissipation layer is located on two sides of the first cavity.

In some embodiments, the first electrode layer is located on the first cavity and is covered with the first piezoelectric layer. In some embodiments, the first piezoelectric layer comprises a sixth protruding part located over the first electrode layer, and the second electrode layer is located on the first piezoelectric layer and comprises a seventh protruding part located on the sixth protruding part. In some embodiments, the sixth protruding part is of at least one of the following shapes: trapezoidal shape and rectangular shape; and the seventh protruding part is of at least one of the following shapes: trapezoidal shape and rectangular shape.

An embodiment of the invention further provides a filter device which comprises, but is not limited to, at least one BAW resonance device provided by one of the aforementioned embodiments.

An embodiment of the invention further provides an RF front-end device which comprises, but is not limited to, at least one filter device provided by the aforementioned embodiment, and a power amplification device connected to the filter device.

An embodiment of the invention further provides an RF front-end device which comprises, but is not limited to, at least one filter device provided by the aforementioned embodiment, and a low-noise amplification device connected to the filter device.

An embodiment of the invention further provides an RF front-end device which comprises, but is not limited to, a multiplexing device, wherein the multiplexing device comprises at least one filter device provided by the aforementioned embodiment.

### BENEFICIAL EFFECTS OF THE INVENTION

### Beneficial Effects

As can be seen from the foregoing description, the present invention has the following beneficial effects: a BAW resonance device comprises a heat-dissipation layer, which is disposed on a substrate or an intermediate layer to improve or flexibly adjust the heat-dissipation performance of the BAW resonance device, for example, the Q value can be increased and the heat-dissipation performance can be compensated.

### BRIEF DESCRIPTION OF THE SEVERAL VIEWS OF THE DRAWINGS

### Description of the Drawings

FIG. 1 is a structural diagram of a BAW filter 100;

FIG. 2 is a structural diagram of cross-section A of an FBAR 200;

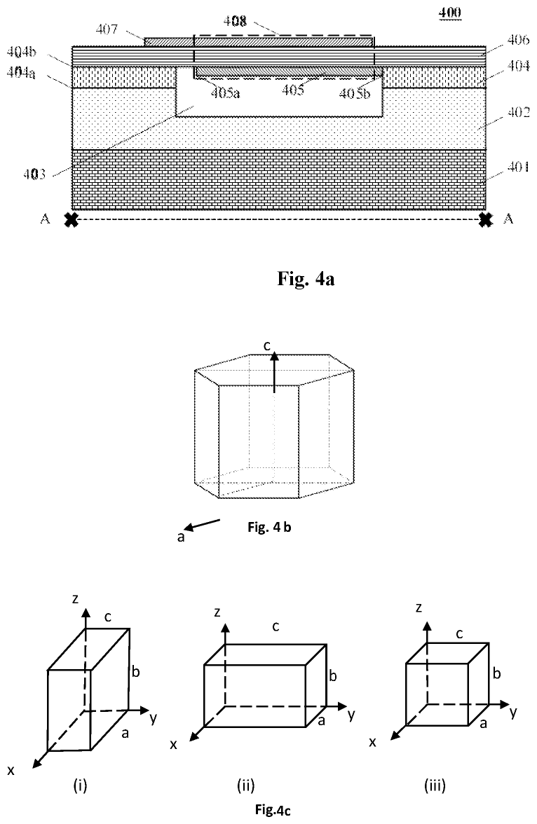

FIG. 3 is a structural diagram of cross-section A of a BAW resonance device 300 in an embodiment of the invention;

FIG. 4a is a structural diagram of cross-section A of a BAW resonance device 400 in an embodiment of the invention;

FIG. 4b is a structural diagram of a crystal of a hexagonal system;

FIG. 4c (i) is a structural diagram of a crystal of an orthorhombic system;

FIG. 4c (ii) is a structural diagram of a crystal of a tetragonal system;

FIG. 4c (iii) is a structural diagram of a crystal of a cubic system;

FIG. 5 is a structural diagram of cross-section A of a BAW resonance device 500 in an embodiment of the invention;

FIG. 6 is a structural diagram of cross-section A of a BAW resonance device 600 in an embodiment of the invention;

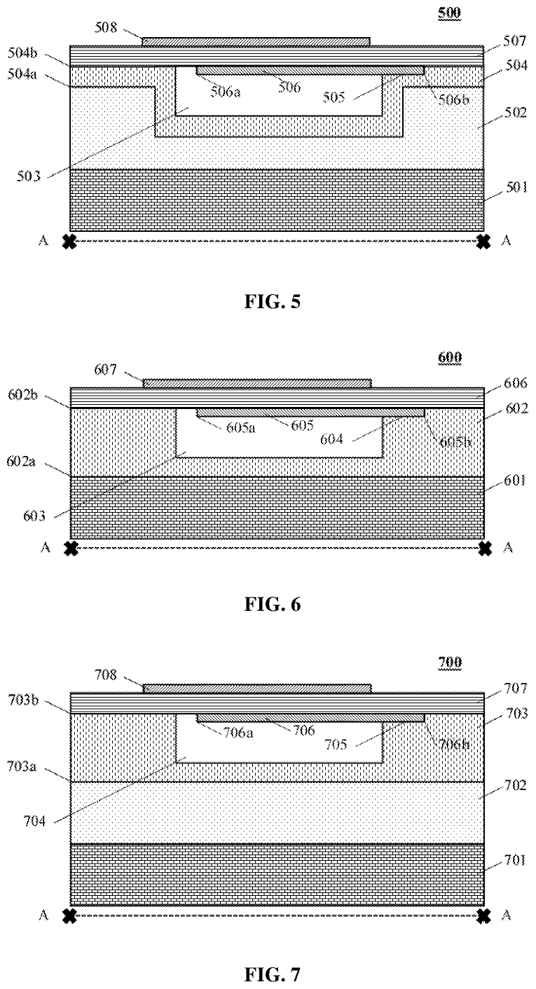

FIG. 7 is a structural diagram of cross-section A of a BAW resonance device 700 in an embodiment of the invention;

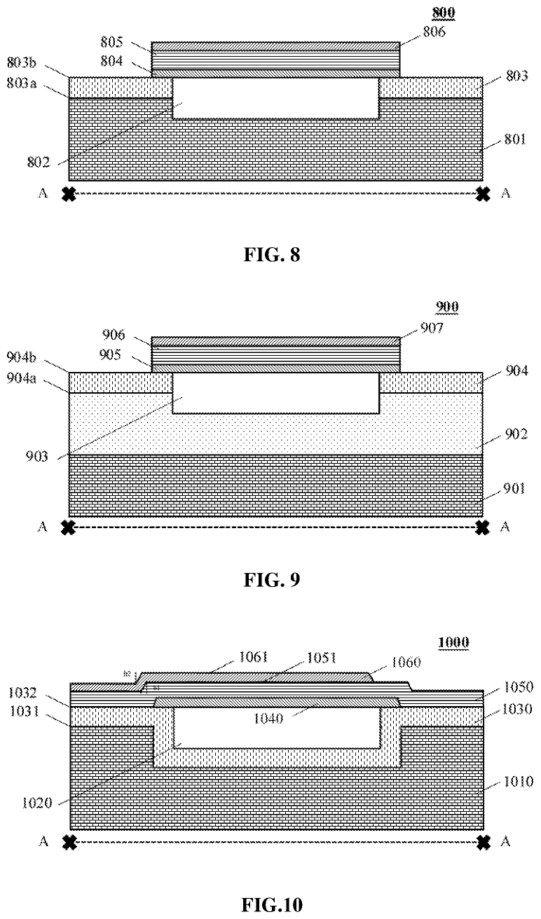

FIG. 8 is a structural diagram of cross-section A of a BAW resonance device 800 in an embodiment of the invention;

FIG. 9 is a structural diagram of cross-section A of a BAW resonance device 900 in an embodiment of the invention;

FIG. 10 is a structural diagram of cross-section A of a BAW resonance device 1000 in an embodiment of the invention;

FIG. 11 is a structural diagram of cross-section A of a BAW resonance device 1100 in an embodiment of the invention;

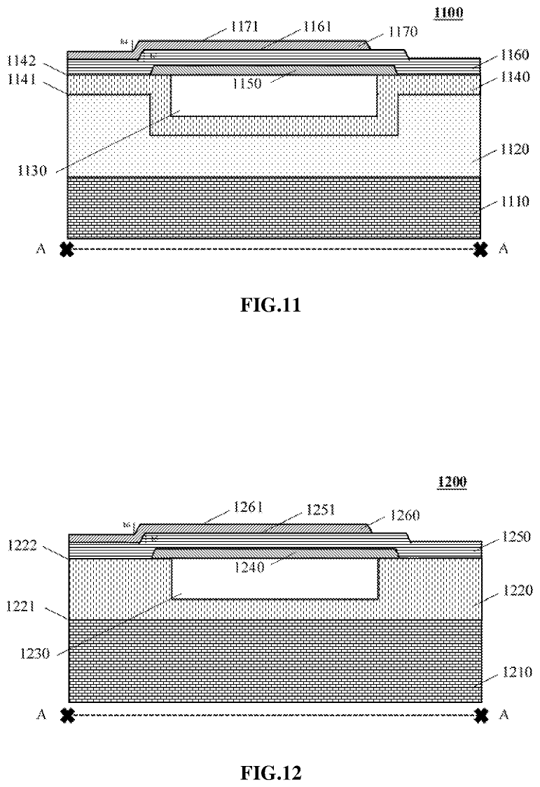

FIG. 12 is a structural diagram of cross-section A of a BAW resonance device 1200 in an embodiment of the invention;

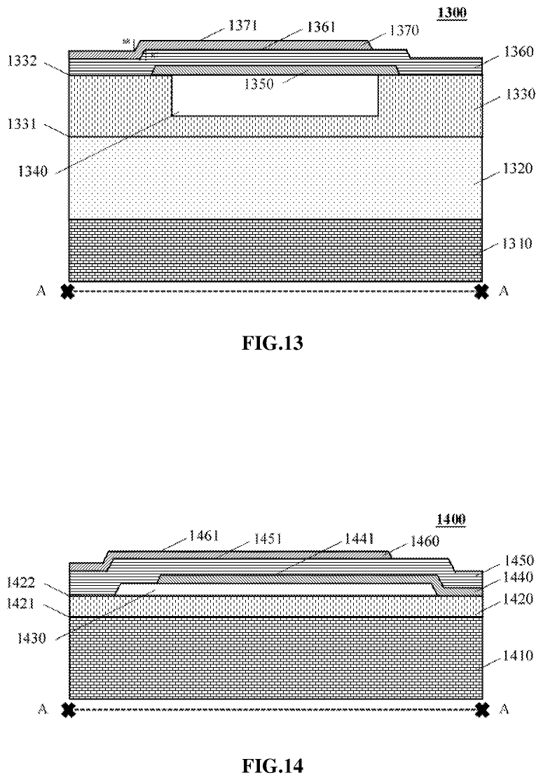

FIG. 13 is a structural diagram of cross-section A of a BAW resonance device 1300 in an embodiment of the invention;

FIG. 14 is a structural diagram of cross-section A of a BAW resonance device 1400 in an embodiment of the invention;

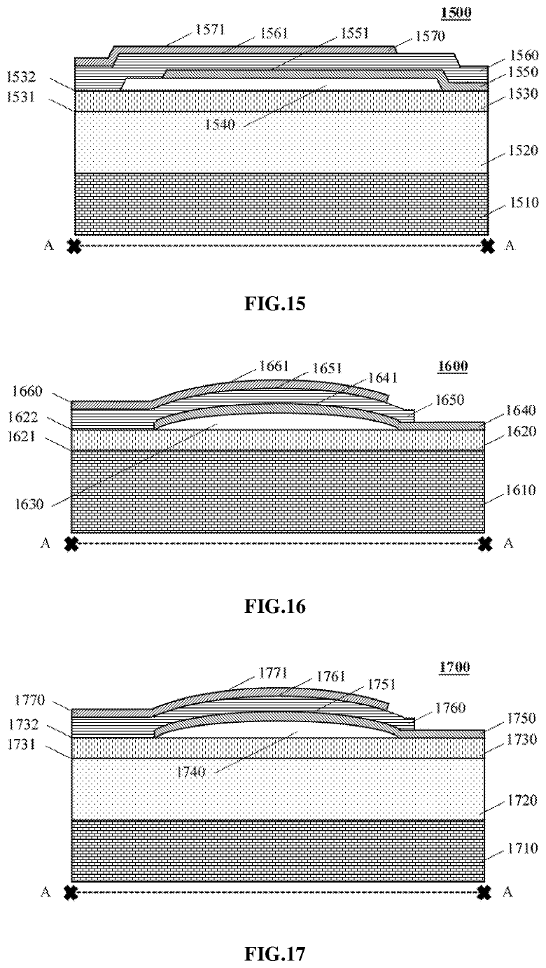

FIG. 15 is a structural diagram of cross-section A of a BAW resonance device 1500 in an embodiment of the invention;

FIG. 16 is a structural diagram of cross-section A of a BAW resonance device 1600 in an embodiment of the invention;

FIG. 17 is a structural diagram of cross-section A of a BAW resonance device 1700 in an embodiment of the invention.

### DETAILED DESCRIPTION OF THE INVENTION

### Detailed Description of the Invention

To gain a better understanding of the purposes, features and advantages of the invention, the specific implementations of the invention are expounded below in conjunction with the accompanying drawings.

Many specific details are given in the following description to obtain a comprehensive appreciation of the invention. Clearly, the invention can also be implemented through other embodiments different from those described hereinafter. Hence, the invention is not limited to the specific embodiments disclosed below.

As described in the description of related art, the heat-dissipation capacity of BAW resonance devices depends on the heat-dissipation capacity of the substrate, so that there remains limited room to improve or adjust the heat-dissipation capacity of the BAW resonance devices.

The inventor of the invention finds that a BAW resonance device may comprise a heat-dissipation layer, which is disposed on a substrate or an intermediate layer to improve or flexibly adjust the heat-dissipation performance of the BAW resonance device (for example, the heat-dissipation layer can increase the Q value of the BAW resonance device and compensate for the heat-dissipation performance of the BAW resonance device).

An embodiment of the invention provides a BAW resonance device which comprises a first passive part, a first active part and a first cavity, wherein the first passive part comprises a first substrate and a first heat-dissipation layer located over the first substrate; the first active part comprises a first piezoelectric layer, a first electrode layer and a second electrode layer, wherein the first piezoelectric layer is located over the first passive part and has a first side and a second side opposite to the first side, the first passive part is located on the first side, the first electrode layer is also located on the first side and is disposed between the first passive part and the first piezoelectric layer, and the second electrode layer is located on the second side; and the first cavity is located on the first side and is disposed between the first passive part and the first piezoelectric layer, and at least one part of the first electrode layer is located on or in the first cavity.

In some embodiments, the first heat-dissipation layer is made of, but not limited to, at least one of the following materials: aluminum nitride, silicon carbide and diamond. In some embodiments, the thickness of the first heat-dissipation layer is, but not limited to, 0.1 μm-5 μm.

In some embodiments, the first cavity is inlaid in the first passive part and is located between the first substrate and the first piezoelectric layer, and the first heat-dissipation layer is located on two sides of the first cavity.

In some embodiments, the first cavity is inlaid in the first passive part and is located between the first heat-dissipation layer and the first piezoelectric layer, and the first heat-dissipation layer is located on two sides of the first cavity.

In some embodiments, the first electrode layer is located in the first cavity, and the first piezoelectric layer is located on the first electrode layer.

In some embodiments, the first heat-dissipation layer has a first groove; the first electrode layer has a first end and a second end opposite to the first end, wherein the first end is located in the first cavity, the second end is located in the first groove; and the first piezoelectric layer is located on the first electrode layer.

In some embodiments, the first cavity is inlaid in the first passive part and is located between the first substrate and the first electrode layer, and the first heat-dissipation layer is located on two sides of the first cavity.

In some embodiments, the first cavity is inlaid in the first passive part and is located between the first heat-dissipation layer and the first electrode layer, and the first heat-dissipation layer is located on two sides of the first cavity.

In some embodiments, the first electrode layer is located on the first cavity and is covered with the first piezoelectric layer. In some embodiments, the first piezoelectric layer comprises a first protruding part located over the first electrode layer, and the second electrode layer is located on the first piezoelectric layer and comprises a second protruding part located over the first protruding part. In some embodiments, the first protruding part is of, but not limited to, at least one of the following shapes: trapezoidal shape and rectangular shape; and the second protruding part is of, but not limited to, at least one of the following shapes: trapezoidal shape and rectangular shape.

In some embodiments, the first cavity is located between the first heat-dissipation layer and the first piezoelectric layer and is disposed on the first heat-dissipation layer.

In some embodiments, the first electrode layer is located on the first heat-dissipation layer and comprises a third protruding part located on the first cavity; the first piezoelectric layer covers the first cavity and comprises a fourth protruding part located over the third protruding part; and the second electrode layer is located on the first piezoelectric layer and comprises a fifth protruding part located over the fourth protruding part. In some embodiments, the third protruding part is of, but not limited to, at least one of the following shapes: trapezoidal shape, arch shape and rectangular shape; the fourth protruding part is of, but not limited to, at least one of the following shapes: trapezoidal shape, arch shape and rectangular shape; and the fifth protruding part is of, but not limited to, at least one of the following shapes: trapezoidal shape, arch shape and rectangular shape.

In some embodiments, the first passive part further comprises a first intermediate layer located between the first substrate and the first heat-dissipation layer and disposed on the first substrate, and the first heat-dissipation layer is located on the first intermediate layer.

In some embodiments, the first intermediate layer is made of, but not limited to, at least one of the following materials: polymer, insulating dielectric and polysilicon. In some embodiments, the thickness of the first intermediate layer is, but not limited to, 0.1 μm-10 μm.

In some embodiments, the first cavity is inlaid in the first passive part and is located between the first intermediate layer and the first piezoelectric layer, and the first heat-dissipation layer is located on two sides of the first cavity.

In some embodiments, the first electrode layer is located in the first cavity, and the first piezoelectric layer is located on the first electrode layer.

In some embodiments, the first heat-dissipation layer comprises a second groove; the first electrode layer has a third end and a fourth end opposite to the third end, wherein the third end is located in the first cavity, and the fourth end is located in the second groove; and the first piezoelectric layer is located on the first electrode layer.

In some embodiments, the first cavity is inlaid in the first passive part and is located between the first intermediate layer and the first electrode layer, and the first heat-dissipation layer is located on two sides of the first cavity.

In some embodiments, the first electrode layer is located on the first cavity and is covered with the first piezoelectric layer. In some embodiments, the first piezoelectric layer comprises a sixth protruding part located over the first electrode layer; and the second electrode layer is located on the first piezoelectric layer and comprises a seventh protruding part located on the sixth protruding part. In some embodiments, the sixth protruding part is of, but not limited to, at least one of the following shapes: trapezoidal shape and rectangular shape; and the seventh protruding part is of, but not limited to, at least one of the following shapes: trapezoidal shape and rectangular shape.

It should be noted that the BAW resonance device comprises the first heat-dissipation layer, which is located on the first substrate or the first intermediate layer and can improve or flexibly adjust the heat-dissipation performance of the BAW resonance device (for example, the heat-dissipation layer can increase the Q value of the BAW resonance device and compensate for the heat-dissipation performance of the BAW resonance device).

An embodiment of the invention further provides a filter device which comprises, but is not limited to, at least one BAW resonance device provided by one of the aforementioned embodiments.

An embodiment of the invention further provides an RF front-end device which comprises, but is not limited to, at least one first filter device provided by the aforementioned embodiment, and a power amplification device connected to the first filter device.

An embodiment of the invention further provides an RF front-end device which comprises, but is not limited to, at least one second filter device provided by the aforementioned embodiment, and a low-noise amplification device connected to the second filter device.

An embodiment of the invention further provides an RF front-end device which comprises, but is not limited to, a multiplexing device, wherein the multiplexing device comprises at least one third filter device provided by the aforementioned embodiment.

FIG. 3 to FIG. 17 illustrate multiple specific embodiments of the invention. Resonance devices provided by the multiple specific embodiments are of different structures. Obviously, the invention can also be implemented by means of other embodiments different from those described herein. Hence, the invention is not limited to the specific embodiments disclosed below.

FIG. 3 is a structural diagram of cross-section A of a BAW resonance device 300 in an embodiment of the invention.

As shown in FIG. 3, an embodiment of the invention provides a BAW resonance device 300 which comprises a substrate 301, a cavity 302, a heat-dissipation layer 303, an electrode layer 304, a piezoelectric layer 305 and an electrode layer 306, wherein the cavity 302 is inlaid in the substrate 301; the heat-dissipation layer 303 is disposed on the substrate 301, is located on two sides of the cavity 302, and has a first side 303a and a second side 303b opposite to the first side 303a, and the substrate 301 is located on the first side 303a; the electrode layer 304 has a first end 304a and a second end 304b opposite to the first end 304a, the first end 304a is located in the cavity 302, and the second end 304b contacts with the heat-dissipation layer 303; the piezoelectric layer 305 is located on the second side 303b, is disposed on the electrode layer 304, and covers the cavity 302; the electrode layer 306 is located on the second side 303b and is disposed on the piezoelectric layer 305; a resonance region 307 (namely, an overlap region of the electrode layer 304 and the electrode layer 306) is suspended with respect to the cavity 302 and does not overlap with the heat-dissipation layer 303, so that a vertical projection, perpendicular to the piezoelectric layer 305, of the resonance region 307 is located in the cavity 302.

In this embodiment, the substrate 301 is made of, but not limited to, at least one of the following materials: silicon, silicon carbide, glass, gallium arsenide and gallium nitride.

In this embodiment, the thickness of the heat-dissipation layer 303 is, but not limited to, 0.1 μm-5 μm. In this embodiment, the heat-dissipation layer 303 is made of, but not limited to, at least one of the following materials: aluminum nitride, silicon carbide and diamond. It should be noted that the heat-dissipation layer 303 is made of a material with the thermal conductivity better than that of the substrate 301, thus improving the heat-dissipation performance of the resonance device.

In this embodiment, the electrode layer 304 is located in the cavity 302. In this embodiment, the electrode layer 304 is made of, but not limited to, at least one of the following materials: molybdenum, ruthenium, tungsten, platinum, iridium, aluminum and beryllium. In another embodiment, the lower electrode layer is located in the cavity and does not contact with the heat-dissipation layer.

In this embodiment, the piezoelectric layer 305 is a flat layer and covers the heat-dissipation layer 303. In this embodiment, the piezoelectric layer 305 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the electrode layer 306 is made of, but not limited to, at least one of the following materials: molybdenum, ruthenium, tungsten, platinum, iridium, aluminum and beryllium.

FIG. 4a is a structural diagram of cross-section A of a BAW resonance device 400 in an embodiment of the invention.

As shown in FIG. 4a, an embodiment of the invention provides a BAW resonance device 400 which comprises a substrate 401, an intermediate layer 402, a cavity 403, a heat-dissipation layer 404, an electrode layer 405, a piezoelectric layer 406 and an electrode layer 407, wherein the intermediate layer 402 is located on the substrate 401; the cavity 403 is inlaid in the intermediate layer 402; the heat-dissipation layer 404 is disposed on the intermediate layer 402, is located on two sides of the cavity 403, and has a first side 404a and a second side 404b opposite to the first side 404a, and the intermediate layer 402 is located on the first side 404a; the electrode layer 405 has a first end 405a and a second end 405b opposite to the first end 405a, the first end 405a is located in the cavity 403, and the second end 405b contacts with the heat-dissipation layer 404; the piezoelectric layer 406 is located on the second side 404b, is disposed on the electrode layer 405, and covers the cavity 403; the electrode layer 407 is located on the second side 404b and is disposed on the piezoelectric layer 406; and a resonance region 408 (namely, an overlap region of the electrode layer 405 and the electrode layer 407) is suspended with respect to the cavity 403 and does not overlap with the heat-dissipation layer 404, so that a vertical projection, perpendicular to the piezoelectric layer 406, of the resonance region 408 is located in the cavity 403.

It should be noted that the acoustic impedance of the heat-dissipation layer 404 is different from that of the intermediate layer 402, so that the difference in acoustic impedance between the resonance region 408 and a non-resonance region can be increased to prevent acoustic waves generated in the resonance region 408 from leaking into the non-resonance region.

In this embodiment, the substrate 401 is made of, but not limited to, at least one of the following materials: silicon, silicon carbide, glass, gallium arsenide and gallium nitride.

In this embodiment, the thickness of the intermediate layer 402 is, but not limited to, 0.1 μm-10 μm. In this embodiment, the intermediate layer 402 is made of, but not limited to, at least one of the following materials: polymer, insulating dielectric and polysilicon. In this embodiment, the polymer includes, but is not limited to, at least one of benzocyclobutene (BCB), photosensitive epoxy resin photoresist (such as SU-8) and polyimide. In this embodiment, the insulating dielectric includes, but is not limited to, at least one of aluminum nitride, silicon dioxide, silicon nitride and titanium oxide. It should be noted that the thermal conductivity of the material of the intermediate layer 402 is lower than that of the material of the substrate 401.

In this embodiment, the thickness of the heat-dissipation layer 404 is, but not limited to, 0.1 μm-5 μm. In this embodiment, the heat-dissipation layer 404 is made of, but not limited to, at least one of the following materials: aluminum nitride, silicon carbide and diamond. It should be noted that the heat-dissipation layer 404 is made of a material with the thermal conductivity better than that of the substrate 401, thus compensating for the heat-dissipation performance of the resonance device.

In this embodiment, the electrode layer 405 is located in the cavity 403. In this embodiment, the electrode layer 405 is made of, but not limited to, at least one of the following materials: molybdenum, ruthenium, tungsten, platinum, iridium, aluminum and beryllium. In another embodiment, the lower electrode layer is located in the cavity and does not contact with the heat-dissipation layer.

In this embodiment, the piezoelectric layer 406 is a flat layer and covers the heat-dissipation layer 404. In this embodiment, the piezoelectric layer 406 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the piezoelectric layer 406 comprises multiple crystals, wherein the multiple crystals include a first crystal and a second crystal, and the first crystal and the second crystal are any two crystals of the multiple crystals. As is known to those skilled in the art that the orientation and plane of crystals can be represented by coordinate systems. For example, as shown in FIG. 4b, a crystal of a hexagonal system, such as an aluminum nitride crystal, can be represented by an ac three-dimensional coordinate system (including an a-axis and a c-axis). For another example, as shown in FIG. 4c, crystals of an orthorhombic system (a≠b≠c ) (i), a tetragonal system (a=b≠c) (ii) and a cubic system (a=b=c) (iii) can be represented by an xyz three-dimensional coordinate system (including an x-axis, a y-axis and a z-axis). In addition to these two examples, the crystals can also be represented by other coordinate systems known by those skilled in the art, and thus, the invention is not limited to the two aforementioned examples.

In this embodiment, the first crystal may be represented by a first three-dimensional coordinate system, and the second crystal may be represented by a second three-dimensional coordinate system, wherein the first three-dimensional coordinate system at least includes a first coordinate axis in a first direction and a third coordinate axis in a third direction, the second three-dimensional coordinate system at least includes a second coordinate axis in a second direction and a fourth coordinate axis in a fourth direction, the first coordinate axis corresponds to the height of the first crystal, and the second coordinate axis corresponds to the height of the second crystal.

In this embodiment, the first direction is identical with or opposite to the second direction. It should be noted that when the first direction is identical with the second direction, an angle between a vector in the first direction and a vector in the second direction ranges from 0° to 5°, and that when the first direction is opposite to the second direction, the angle between the vector in the first direction and the vector in the second direction ranges from 175° to 180°.

In another embodiment, the first three-dimensional coordinate system is an ac three-dimensional coordinate system, wherein the first coordinate axis is a first c-axis, and the third coordinate axis is a first a-axis; and the second three-dimensional coordinate system is also an ac three-dimensional coordinate system, wherein the second coordinate axis is a second c-axis, the fourth coordinate axis is a second a-axis, and the first c-axis and the second c-axis are in the same direction or in opposite directions.

In another embodiment, the first three-dimensional coordinate system further includes a fifth coordinate axis in a fifth direction, and the second three-dimensional coordinate system further includes a sixth coordinate axis in a sixth direction. In another embodiment, the first direction is identical with or opposite to the second direction, and the third direction is identical with or opposite to the fourth direction. It should be noted that when the third direction is identical with the fourth direction, an angle between a vector in the third direction and a vector in the fourth direction ranges from 0° to 5°, and that when the third direction is opposite to the fourth direction, the angle between the vector in the third direction and the vector in the fourth direction ranges from 175° to 180°.

In another embodiment, the first three-dimensional coordinate system is an xyz three-dimensional coordinate system, wherein the first coordinate axis is a first z-axis, the third coordinate axis is a first y-axis, and the fifth coordinate axis is a first x-axis; and the second three-dimensional coordinate system is also an xyz three-dimensional coordinate system, wherein the second coordinate axis is a second z-axis, the fourth coordinate axis is a second y-axis, and the sixth coordinate axis is a second x-axis. In another embodiment, the first z-axis and the second z-axis are in the same direction, and the first y-axis and the second y-axis are in the same direction. In another embodiment, the first z-axis and the second z-axis are in opposite directions, and the first y-axis and the second y-axis are in opposite directions. In another embodiment, the first z-axis and the second z-axis are in the same direction, and the first y-axis and the second y-axis are in opposite directions. In another embodiment, the first z-axis and the second z-axis are in opposite directions, and the first y-axis and the second y-axis are in the same direction.

In this embodiment, the piezoelectric layer 406 comprises multiple crystals, wherein the full width at half maximum (FWHM) of rocking curves of the multiple crystals is less than 2.5°. It should be noted that the rocking curve depicts the angular divergence of a specific crystal plane (determined by the diffraction angle) in a sample and is represented by a planar coordinate system, wherein the horizontal axis represents the angle between the crystal plane and the sample, the vertical axis represents the diffraction intensity of the crystal plane under a certain angle, the rocking curve indicates the crystal lattice quality, and the smaller the FWHM, the higher the crystal lattice quality. In addition, the FWHM indicates the distance between points with two consecutive functional values equal to half of the peak value in one peak of a function.

It should be noted that the piezoelectric layer 406 formed on a plane does not comprise distinctly turning crystals, so that the electromechanical coupling coefficient and Q value of the resonance device are increased.

In this embodiment, the electrode layer 407 is made of, but not limited to, at least one of the following materials: molybdenum, ruthenium, tungsten, platinum, iridium, aluminum and beryllium.

FIG. 5 is a structural diagram of cross-section A of a BAW resonance device 500 in an embodiment of the invention.

As shown in FIG. 5, an embodiment of the invention provides a BAW resonance device 500 which comprises a substrate 501, an intermediate layer 502, a cavity 503, a heat-dissipation layer 504, an electrode layer 506, a piezoelectric layer 507 and an electrode layer 508, wherein the intermediate layer 502 is located on the substrate 501; the cavity 503 is inlaid in the intermediate layer 502; the heat-dissipation layer 504 is disposed on the intermediate layer 502, is located on two sides of the cavity 503, covers the side wall and bottom of the cavity 503, and has a first side 504a and a second side 504b opposite to the first side 504a, the intermediate layer 502 is located on the first side 504a, the heat-dissipation layer 504 further has a groove 505 located on one side of the cavity 503 and communicated with the cavity 503, and the depth of the groove 505 is smaller than that of the cavity 503; the electrode layer 506 has first end 506a and a second end 506b opposite to the first end 506a, the first end 506a is located in the cavity 503, the second end 506b is located in the groove 505, and the depth of the groove 505 is equal to the thickness of the electrode layer 506; the piezoelectric layer 507 is located on the second side 504b, is disposed on the electrode layer 506, and covers the cavity 503; the electrode layer 508 is located on the second side 504b and is disposed on the piezoelectric layer 507; and a resonance region (namely, an overlap region of the electrode layer 506 and the electrode layer 508) is suspended with respect to the cavity 503 and does not overlap with the heat-dissipation layer 504, so that a vertical projection, perpendicular to the piezoelectric layer 507, of the resonance region is located in the cavity 504.

It should be noted that the acoustic impedance of the heat-dissipation layer 504 is different from that of the intermediate layer 502, so that the difference in acoustic impedance between the resonance region and a non-resonance region can be increased to prevent acoustic waves generated in the resonance region from leaking into the non-resonance region.

In this embodiment, the substrate 501 is made of, but not limited to, at least one of the following materials: silicon, silicon carbide, glass, gallium arsenide and gallium nitride.

In this embodiment, the thickness of the intermediate layer 502 is, but not limited to, 0.1 μm-10 μm. In this embodiment, the intermediate layer 502 is made of, but not limited to, at least one of the following materials: polymer, insulating dielectric and polysilicon. In this embodiment, the polymer includes, but is not limited to, at least one of benzocyclobutene (BCB), photosensitive epoxy resin photoresist (such as SU-8) and polyimide. In this embodiment, the insulating dielectric includes, but is not limited to, at least one of aluminum nitride, silicon dioxide, silicon nitride and titanium oxide. It should be noted that the thermal conductivity of the material of the intermediate layer 502 is lower than that of the material of the substrate 501.

In this embodiment, the thickness of the heat-dissipation layer 504 is, but not limited to, 0.1 μm-5 μm. In this embodiment, the heat-dissipation layer 504 is made of, but not limited to, at least one of the following materials: aluminum nitride, silicon carbide and diamond. It should be noted that the heat-dissipation layer 504 is made of a material with the thermal conductivity better than that of the substrate 501, thus compensating for the heat-dissipation performance of the resonance device.

In this embodiment, the electrode layer 506 is made of, but not limited to, at least one of the following materials: molybdenum, ruthenium, tungsten, platinum, iridium, aluminum and beryllium.

In this embodiment, the piezoelectric layer 507 is a flat layer and covers the heat-dissipation layer 504. In this embodiment, the piezoelectric layer 507 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the piezoelectric layer 507 comprises multiple crystals, wherein the multiple crystals include a first crystal and a second crystal, and the first crystal and the second crystal are any two crystals of the multiple crystals.

In this embodiment, the first crystal may be represented by a first three-dimensional coordinate system, and the second crystal may be represented by a second three-dimensional coordinate system, wherein the first three-dimensional coordinate system at least includes a first coordinate axis in a first direction and a third coordinate axis in a third direction, the second three-dimensional coordinate system at least includes a second coordinate axis in a second direction and a fourth coordinate axis in a fourth direction, the first coordinate axis corresponds to the height of the first crystal, and the second coordinate axis corresponds to the height of the second crystal.

In this embodiment, the first direction is identical with or opposite to the second direction. It should be noted that when the first direction is identical with the second direction, an angle between a vector in the first direction and a vector in the second direction ranges from 0° to 5°, and that when the first direction is opposite to the second direction, the angle between the vector in the first direction and the vector in the second direction ranges from 175° to 180°.

In another embodiment, the first three-dimensional coordinate system is an ac three-dimensional coordinate system, wherein the first coordinate axis is a first c-axis, and the third coordinate axis is a first a-axis; and the second three-dimensional coordinate system is also an ac three-dimensional coordinate system, wherein the second coordinate axis is a second c-axis, the fourth coordinate axis is a second a-axis, and the first c-axis and the second c-axis are in the same direction or in opposite directions.

In another embodiment, the first three-dimensional coordinate system further includes a fifth coordinate axis in a fifth direction, and the second three-dimensional coordinate system further includes a sixth coordinate axis in a sixth direction. In another embodiment, the first direction is identical with or opposite to the second direction, and the third direction is identical with or opposite to the fourth direction. It should be noted that when the third direction is identical with the fourth direction, an angle between a vector in the third direction and a vector in the fourth direction ranges from 0° to 5°, and that when the third direction is opposite to the fourth direction, the angle between the vector in the third direction and the vector in the fourth direction ranges from 175° to 180°.

In another embodiment, the first three-dimensional coordinate system is an xyz three-dimensional coordinate system, wherein the first coordinate axis is a first z-axis, the third coordinate axis is a first y-axis, and the fifth coordinate axis is a first x-axis; and the second three-dimensional coordinate system is also an xyz three-dimensional coordinate system, wherein the second coordinate axis is a second z-axis, the fourth coordinate axis is a second y-axis, and the sixth coordinate axis is a second x-axis. In another embodiment, the first z-axis and the second z-axis are in the same direction, and the first y-axis and the second y-axis are in the same direction. In another embodiment, the first z-axis and the second z-axis are in opposite directions, and the first y-axis and the second y-axis are in opposite directions. In another embodiment, the first z-axis and the second z-axis are in the same direction, and the first y-axis and the second y-axis are in opposite directions. In another embodiment, the first z-axis and the second z-axis are in opposite directions, and the first y-axis and the second y-axis are in the same direction.

In this embodiment, the piezoelectric layer 507 comprises multiple crystals, wherein the FWHM of rocking curves of the multiple crystals is less than 2.5°.

It should be noted that the piezoelectric layer 507 formed on a plane does not comprise distinctly turning crystals, so that the electromechanical coupling coefficient and Q value of the resonance device are increased.

In this embodiment, the electrode layer 508 is made of, but not limited to, at least one of the following materials: molybdenum, ruthenium, tungsten, platinum, iridium, aluminum and beryllium.

FIG. 6 is a structural diagram of cross-section A of a BAW resonance device in an embodiment of the invention.

As shown in FIG. 6, an embodiment of the invention provides a BAW resonance device 600 which comprises a substrate 601, a heat-dissipation layer 602, an electrode layer 605, a piezoelectric layer 606 and an electrode layer 607, wherein the heat-dissipation layer 602 is located on the substrate 601 and has a first side 602a and a second side 602b opposite to the first side 602a, the substrate 601 is located on the first side 602a, the heat-dissipation layer 602 further has a cavity 603 and a groove 604 which are located on the second side 602b, the groove 604 is located on one side of the cavity 603 and is communicated with the cavity 603, and the depth of the groove 604 is smaller than that of the cavity 603; the electrode layer 605 has a first end 605a and a second end 605b opposite to the first end 605a, the first end 605a is located in the cavity 603, the second end 605b is located in the groove 604, and the depth of the groove 604 is equal to the thickness of the electrode layer 605; the piezoelectric layer 606 is located on the second side 602b, is disposed on the electrode layer 605, and covers the cavity 603; the electrode layer 607 is located on the second side 602b and is disposed on the piezoelectric layer 606; and a resonance region (namely, an overlap region of the electrode layer 605 and the electrode layer 607) is suspended with respect to the cavity 603 and does not overlap with the heat-dissipation layer 602, so that a vertical projection, perpendicular to the piezoelectric layer 606, of the resonance region is located in the cavity 603.

In this embodiment, the substrate 601 is made of, but not limited to, at least one of the following materials: silicon, silicon carbide, glass, gallium arsenide and gallium nitride.

In this embodiment, the thickness of the heat-dissipation layer 602 is, but not limited to, 0.1 μm-5 μm. In this embodiment, the heat-dissipation layer 602 is made of, but not limited to, at least one of the following materials: aluminum nitride, silicon carbide and diamond. It should be noted that the heat-dissipation layer 602 is made of a material with the thermal conductivity better than that of the substrate 601, thus improving the heat-dissipation performance of the resonance device.

In this embodiment, the electrode layer 605 is made of, but not limited to, at least one of the following materials: molybdenum, ruthenium, tungsten, platinum, iridium, aluminum and beryllium.

In this embodiment, the piezoelectric layer 606 is a flat layer and covers the heat-dissipation layer 602. In this embodiment, the piezoelectric layer 606 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the piezoelectric layer 606 comprises multiple crystals, wherein the multiple crystals include a first crystal and a second crystal, and the first crystal and the second crystal are any two crystals of the multiple crystals.

In this embodiment, the first crystal may be represented by a first three-dimensional coordinate system, and the second crystal may be represented by a second three-dimensional coordinate system, wherein the first three-dimensional coordinate system at least includes a first coordinate axis in a first direction and a third coordinate axis in a third direction, the second three-dimensional coordinate system at least includes a second coordinate axis in a second direction and a fourth coordinate axis in a fourth direction, the first coordinate axis corresponds to the height of the first crystal, and the second coordinate axis corresponds to the height of the second crystal.

In this embodiment, the first direction is identical with or opposite to the second direction. It should be noted that when the first direction is identical with the second direction, an angle between a vector in the first direction and a vector in the second direction ranges from 0° to 5°, and that when the first direction is opposite to the second direction, the angle between the vector in the first direction and the vector in the second direction ranges from 175° to 180°.

In another embodiment, the first three-dimensional coordinate system is an ac three-dimensional coordinate system, wherein the first coordinate axis is a first c-axis, and the third coordinate axis is a first a-axis; and the second three-dimensional coordinate system is also an ac three-dimensional coordinate system, wherein the second coordinate axis is a second c-axis, the fourth coordinate axis is a second a-axis, and the first c-axis and the second c-axis are in the same direction or in opposite directions.

In another embodiment, the first three-dimensional coordinate system further includes a fifth coordinate axis in a fifth direction, and the second three-dimensional coordinate system further includes a sixth coordinate axis in a sixth direction. In another embodiment, the first direction is identical with or opposite to the second direction, and the third direction is identical with or opposite to the fourth direction. It should be noted that when the third direction is identical with the fourth direction, an angle between a vector in the third direction and a vector in the fourth direction ranges from 0° to 5°, and that when the third direction is opposite to the fourth direction, the angle between the vector in the third direction and the vector in the fourth direction ranges from 175° to 180°.

In another embodiment, the first three-dimensional coordinate system is an xyz three-dimensional coordinate system, wherein the first coordinate axis is a first z-axis, the third coordinate axis is a first y-axis, and the fifth coordinate axis is a first x-axis; and the second three-dimensional coordinate system is also an xyz three-dimensional coordinate system, wherein the second coordinate axis is a second z-axis, the fourth coordinate axis is a second y-axis, and the sixth coordinate axis is a second x-axis. In another embodiment, the first z-axis and the second z-axis are in the same direction, and the first y-axis and the second y-axis are in the same direction. In another embodiment, the first z-axis and the second z-axis are in opposite directions, and the first y-axis and the second y-axis are in opposite directions. In another embodiment, the first z-axis and the second z-axis are in the same direction, and the first y-axis and the second y-axis are in opposite directions. In another embodiment, the first z-axis and the second z-axis are in opposite directions, and the first y-axis and the second y-axis are in the same direction.

In this embodiment, the piezoelectric layer 606 comprises multiple crystals, wherein the FWHM of rocking curves of the multiple crystals is less than 2.5°.

It should be noted that the piezoelectric layer 606 formed on a plane does not comprise distinctly turning crystals, so that the electromechanical coupling coefficient and Q value of the resonance device are increased.

In this embodiment, the electrode layer 607 is made of, but not limited to, at least one of the following materials: molybdenum, ruthenium, tungsten, platinum, iridium, aluminum and beryllium.

FIG. 7 is a structural diagram of cross-section A of a BAW resonance device 700 in an embodiment of the invention.

As shown in FIG. 7, an embodiment of the invention provides a BAW resonance device 700 which comprises a substrate 701, an intermediate layer 702, a heat-dissipation layer 703, an electrode layer 706, a piezoelectric layer 707 and an electrode layer 708, wherein the intermediate layer 702 is located on the substrate 701; the heat-dissipation layer 703 is located on the intermediate layer 702 and has a first side 703a and a second side 703b opposite to the first side 703a, the intermediate layer 702 is located on the first side 703a, the heat-dissipation layer 703 further has a cavity 704 and a groove 705 which are located on the second side 703b, the groove 705 is located on one side of the cavity 704 and is communicated with the cavity 704, and the depth of the groove 705 is smaller than that of the cavity 704; the electrode layer 706 has a first end 706a and a second end 706b opposite to the first end 706a, the first end 706a is located in the cavity 704, the second end 706b is located in the groove 705, and the depth of the groove 705 is equal to the thickness of the electrode layer 706; the piezoelectric layer 707 is located on the second side 703b, is disposed on the electrode layer 706, and covers the cavity 704; the electrode layer 708 is located on the second side 703b and is disposed on the piezoelectric layer 707; and a resonance region (namely, an overlap region of the electrode layer 706 and the electrode layer 708) is suspended with respect to the cavity 704 and does not overlap with the heat-dissipation layer 703, so that a vertical projection, perpendicular to the piezoelectric layer 707, of the resonance region is located in the cavity 704.

It should be noted that the acoustic impedance of the heat-dissipation layer 703 is different from that of the intermediate layer 702, so that the difference in acoustic impedance between the resonance region and a non-resonance region can be increased to prevent acoustic waves generated in the resonance region from leaking into the non-resonance region.

In this embodiment, the substrate 701 is made of, but not limited to, at least one of the following materials: silicon, silicon carbide, glass, gallium arsenide and gallium nitride.

In this embodiment, the thickness of the intermediate layer 702 is, but not limited to, 0.1 μm-10 μm. In this embodiment, the intermediate layer 702 is made of, but not limited to, at least one of the following materials: polymer, insulating dielectric and polysilicon. In this embodiment, the polymer includes, but is not limited to, at least one of benzocyclobutene (BCB), photosensitive epoxy resin photoresist (such as SU-8) and polyimide. In this embodiment, the insulating dielectric includes, but is not limited to, at least one of aluminum nitride, silicon dioxide, silicon nitride and titanium oxide. It should be noted that the thermal conductivity of the material of the intermediate layer 702 is lower than that of the material of the substrate 701.

In this embodiment, the thickness of the heat-dissipation layer 703 is, but not limited to, 0.1 μm-5 μm. In this embodiment, the heat-dissipation layer 703 is made of, but not limited to, at least one of the following materials: aluminum nitride, silicon carbide and diamond. It should be noted that the heat-dissipation layer 703 is made of a material with the thermal conductivity better than that of the substrate 701, thus compensating for the heat-dissipation performance of the resonance device.

In this embodiment, the electrode layer 706 is made of, but not limited to, at least one of the following materials: molybdenum, ruthenium, tungsten, platinum, iridium,

In this embodiment, the piezoelectric layer 707 is a flat layer and covers the heat-dissipation layer 703. In this embodiment, the piezoelectric layer 707 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the piezoelectric layer 707 comprises multiple crystals, wherein the multiple crystals include a first crystal and a second crystal, and the first crystal and the second crystal are any two crystals of the multiple crystals.

In this embodiment, the first crystal may be represented by a first three-dimensional coordinate system, and the second crystal may be represented by a second three-dimensional coordinate system, wherein the first three-dimensional coordinate system at least includes a first coordinate axis in a first direction and a third coordinate axis in a third direction, the second three-dimensional coordinate system at least includes a second coordinate axis in a second direction and a fourth coordinate axis in a fourth direction, the first coordinate axis corresponds to the height of the first crystal, and the second coordinate axis corresponds to the height of the second crystal.

In this embodiment, the first direction is identical with or opposite to the second direction. It should be noted that when the first direction is identical with the second direction, an angle between a vector in the first direction and a vector in the second direction ranges from 0° to 5°, and that when the first direction is opposite to the second direction, the angle between the vector in the first direction and the vector in the second direction ranges from 175° to 180°.

In another embodiment, the first three-dimensional coordinate system is an ac three-dimensional coordinate system, wherein the first coordinate axis is a first c-axis, and the third coordinate axis is a first a-axis; and the second three-dimensional coordinate system is also an ac three-dimensional coordinate system, wherein the second coordinate axis is a second c-axis, the fourth coordinate axis is a second a-axis, and the first c-axis and the second c-axis are in the same direction or in opposite directions.

In another embodiment, the first three-dimensional coordinate system further includes a fifth coordinate axis in a fifth direction, and the second three-dimensional coordinate system further includes a sixth coordinate axis in a sixth direction. In another embodiment, the first direction is identical with or opposite to the second direction, and the third direction is identical with or opposite to the fourth direction. It should be noted that when the third direction is identical with the fourth direction, an angle between a vector in the third direction and a vector in the fourth direction ranges from 0° to 5°, and that when the third direction is opposite to the fourth direction, the angle between the vector in the third direction and the vector in the fourth direction ranges from 175° to 180°.

In another embodiment, the first three-dimensional coordinate system is an xyz three-dimensional coordinate system, wherein the first coordinate axis is a first z-axis, the third coordinate axis is a first y-axis, and the fifth coordinate axis is a first x-axis; and the second three-dimensional coordinate system is also an xyz three-dimensional coordinate system, wherein the second coordinate axis is a second z-axis, the fourth coordinate axis is a second y-axis, and the sixth coordinate axis is a second x-axis. In another embodiment, the first z-axis and the second z-axis are in the same direction, and the first y-axis and the second y-axis are in the same direction. In another embodiment, the first z-axis and the second z-axis are in opposite directions, and the first y-axis and the second y-axis are in opposite directions.

In another embodiment, the first z-axis and the second z-axis are in the same direction, and the first y-axis and the second y-axis are in opposite directions. In another embodiment, the first z-axis and the second z-axis are in opposite directions, and the first y-axis and the second y-axis are in the same direction.

In this embodiment, the piezoelectric layer 707 comprises multiple crystals, wherein the FWHM of rocking curves of the multiple crystals is less than 2.5°.

It should be noted that the piezoelectric layer 707 formed on a plane does not comprise distinctly turning crystals, so that the electromechanical coupling coefficient and Q value of the resonance device are increased.

In this embodiment, the electrode layer 708 is made of, but not limited to, at least one of the following materials: molybdenum, ruthenium, tungsten, platinum, iridium, aluminum and beryllium.

FIG. 8 is a structural diagram of cross-section A of a BAW resonance device 800 in an embodiment of the invention.

As shown in FIG. 8, an embodiment of the invention provides a BAW resonance device 800 which comprises a substrate 801, a cavity 802, a heat-dissipation layer 803, an electrode layer 804, a piezoelectric layer 805 and an electrode layer 806, wherein the cavity 802 is inlaid in the substrate 801; the heat-dissipation layer 803 is disposed on the substrate 801, is located on two sides of the cavity 802, and has a first side 803a and a second side 803b opposite to the first side 803a, and the substrate 801 is located on the first side 803a; the electrode layer 804 is located on the second side 803b, is disposed on the heat-dissipation layer 803, and covers the cavity 802; the piezoelectric layer 805 is located on the second side 803b, is disposed on the electrode layer 804, and covers the electrode layer 804; the electrode layer 806 is located on the second side 803b, is disposed on the piezoelectric layer 805, and covers the piezoelectric layer 805; and an overlap part of a resonance region (namely, an overlap region of the electrode layer 804 and the electrode layer 806) and the heat-dissipation layer 803 is located on left and right sides of the cavity 802.

In this embodiment, the substrate 801 is made of, but not limited to, at least one of the following materials: silicon, silicon carbide, glass, gallium arsenide and gallium nitride.

In this embodiment, the thickness of the heat-dissipation layer 803 is, but not limited to, 0.1 μm-5 μm. In this embodiment, the heat-dissipation layer 803 is made of, but not limited to, at least one of the following materials: aluminum nitride, silicon carbide and diamond. It should be noted that the heat-dissipation layer 803 is made of a material with the thermal conductivity better than that of the substrate 801, thus improving the heat-dissipation performance of the resonance device.

In this embodiment, the electrode layer 804 is made of, but not limited to, at least one of the following materials: molybdenum, ruthenium, tungsten, platinum, iridium, aluminum and beryllium.

In this embodiment, the piezoelectric layer 805 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the electrode layer 806 is made of, but not limited to, at least one of the following materials: molybdenum, ruthenium, tungsten, platinum, iridium, aluminum and beryllium.

FIG. 9 is a structural diagram of cross-section A of a BAW resonance device 900 in an embodiment of the invention.

As shown in FIG. 9, an embodiment of the invention provides a BAW resonance device 900 which comprises a substrate 901, an intermediate layer 902, a cavity 903, a heat-dissipation layer 904, an electrode layer 905, a piezoelectric layer 906 and an electrode layer 907, wherein the intermediate layer 902 is located on the substrate 901; the cavity 903 is inlaid in the intermediate layer 902; the heat-dissipation layer 904 is disposed on the intermediate layer 902, is located on two sides of the cavity 903, and has a first side 904a and a second side 904b opposite to the first side 904a, and the intermediate layer 902 is located on the first side 904a; the electrode layer 905 is located on the second side 904b, is disposed on the heat-dissipation layer 904, and covers the cavity 903; the piezoelectric layer 906 is located on the second side 904b, is disposed on the electrode layer 905, and covers the electrode layer 905; the electrode layer 907 is located on the second side 904b, is disposed on the piezoelectric layer 906, and covers the piezoelectric layer 906; and an overlap part of a resonance region (namely, an overlap region of the electrode layer 905 and the electrode layer 907) and the heat-dissipation layer 904 is located on two sides of the cavity 903.

It should be noted that the acoustic impedance of the heat-dissipation layer 904 is different from that of the intermediate layer 902, so that the difference in acoustic impedance between the resonance region and a non-resonance region can be increased to prevent acoustic waves generated in the resonance region from leaking into the non-resonance region.

In this embodiment, the substrate 901 is made of, but not limited to, at least one of the following materials: silicon, silicon carbide, glass, gallium arsenide and gallium nitride.

In this embodiment, the thickness of the intermediate layer 902 is, but not limited to, 0.1 μm-5 μm. In this embodiment, the intermediate layer 902 is made of, but not limited to, at least one of the following materials: polymer, insulating dielectric and polysilicon. In this embodiment, the polymer includes, but is not limited to, at least one of benzocyclobutene (BCB), photosensitive epoxy resin photoresist (such as SU-8) and polyimide. In this embodiment, the insulating dielectric includes, but is not limited to, at least one of aluminum nitride, silicon dioxide, silicon nitride and titanium oxide. It should be noted that the thermal conductivity of the material of the intermediate layer 902 is lower than that of the material of the substrate 901.

In this embodiment, the thickness of the heat-dissipation layer 904 is, but not limited to, 0.1 μm-5 μm. In this embodiment, the heat-dissipation layer 904 is made of, but not limited to, at least one of the following materials: aluminum nitride, silicon carbide and diamond. It should be noted that the heat-dissipation layer 904 is made of a material with the thermal conductivity better than that of the substrate 901, thus compensating for the heat-dissipation performance of the resonance device.

In this embodiment, the electrode layer 905 is made of, but not limited to, at least one of the following materials: molybdenum, ruthenium, tungsten, platinum, iridium, aluminum and beryllium.

In this embodiment, the piezoelectric layer 906 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the electrode layer 907 is made of, but not limited to, at least one of the following materials: molybdenum, ruthenium, tungsten, platinum, iridium, aluminum and beryllium.

FIG. 10 is a structural diagram of cross-section A of a BAW resonance device 1000 in an embodiment of the invention.

As shown in FIG. 10, an embodiment of the invention provides a BAW resonance device 1000 which comprises a substrate 1010, a cavity 1020, a heat-dissipation layer 1030, an electrode layer 1040, a piezoelectric layer 1050 and an electrode layer 1060, wherein the cavity 1020 is inlaid in the substrate 1010; the heat-dissipation layer 1030 is disposed on the substrate 1010, is located on two sides of the cavity 1020, covers the side wall and bottom of the cavity 1020, and has a first side 1031 and a second side 1032 opposite to the first side 1031, and the substrate 1010 is located on the first side 1031; the electrode layer 1040 is located on the second side 1032, is disposed on the heat-dissipation layer 1030, and covers the cavity 1020; the piezoelectric layer 1050 is located on the second side 1032, is disposed on the heat-dissipation layer 1030, covers the electrode layer 1040, and comprises a protruding part 1051 located over the electrode layer 1040; the electrode layer 1060 is located on the second side 1032, is disposed on the piezoelectric layer 1050, and comprises a protruding part 1061 located over the protruding part 1051; and an overlap part of a resonance region (namely, an overlap region of the electrode layer 1040 and the electrode layer 1060) and the heat-dissipation layer 1030 is located on one side of the cavity 1020.

In this embodiment, the substrate 1010 is made of, but not limited to, at least one of the following materials: silicon, silicon carbide, glass, gallium arsenide and gallium nitride.

In this embodiment, the thickness of the heat-dissipation layer 1030 is, but not limited to, 0.1 μm-5 μm. In this embodiment, the heat-dissipation layer 1030 is made of, but not limited to, at least one of the following materials: aluminum nitride, silicon carbide and diamond. It should be noted that the heat-dissipation layer 1030 is made of a material with the thermal conductivity better than that of the substrate 1010, thus improving the heat-dissipation performance of the resonance device.

In this embodiment, the electrode layer 1040 is made of, but not limited to, at least one of the following materials: molybdenum, ruthenium, tungsten, platinum, iridium, aluminum and beryllium. In this embodiment, cross-section A of the electrode layer 1040 is trapezoidal. In another embodiment, cross-section A of the lower electrode layer is rectangular.

In this embodiment, the piezoelectric layer 1050 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the protruding height h1 of the protruding part 1051 is equal to or greater than the thickness of the electrode layer 1040. In this embodiment, cross-section A of the protruding part 1051 is trapezoidal. In another embodiment, cross-section A of the first protruding part is rectangular.

In this embodiment, the electrode layer 1060 is made of, but not limited to, at least one of the following materials: molybdenum, ruthenium, tungsten, platinum, iridium, aluminum and beryllium.

In this embodiment, the protruding height h2 of the protruding part 1061 is equal to or greater than the thickness of the electrode layer 1040. In this embodiment, cross-section A of the protruding part 1061 is trapezoidal. In another embodiment, cross-section A of the second protruding part is rectangular.

FIG. 11 is a structural diagram of cross-section A of a BAW resonance device 1100 in an embodiment of the invention.

As shown in FIG. 11, an embodiment of the invention provides a BAW resonance device 1100 which comprises a substrate 1110, an intermediate layer 1120, a cavity 1130, a heat-dissipation layer 1140, an electrode layer 1150, a piezoelectric layer 1160 and an electrode layer 1170, wherein the intermediate layer 1120 is located on the substrate 1110; the cavity 1130 is inlaid in the intermediate layer 1120; the heat-dissipation layer 1140 is disposed on the intermediate layer 1120, is located on two sides of the cavity 1130, covers the side wall and bottom of the cavity 1130, and has a first side 1141 and a second side 1142 opposite to the first side 1141, and the intermediate layer 1120 is located on the first side 1141; the electrode layer 1150 is located on the second side 1142, is disposed on the heat-dissipation layer 1140, and covers the cavity 1130; the piezoelectric layer 1160 is located on the second side 1142, is disposed on the heat-dissipation layer 1140, covers the electrode layer 1150, and comprises a protruding part 1161 located over the electrode layer 1150; the electrode layer 1170 is located on the second side 1142, is disposed on the piezoelectric layer 1160, and comprises a protruding part 1171 located over the protruding part 1161; and an overlap part of a resonance region (namely, an overlap region of the electrode layer 1150 and the electrode layer 1170) and the heat-dissipation layer 1140 is located on one side of the cavity 1130.

It should be noted that the acoustic impedance of the heat-dissipation layer 1140 is different from that of the intermediate layer 1120, so that the difference in acoustic impedance between the resonance region and a non-resonance region can be increased to prevent acoustic waves generated in the resonance region from leaking into the non-resonance region.

In this embodiment, the substrate 1110 is made of, but not limited to, at least one of the following materials: silicon, silicon carbide, glass, gallium arsenide and gallium nitride.

In this embodiment, the thickness of the intermediate layer 1120 is, but not limited to, 0.1 μm-10 μm. In this embodiment, the intermediate layer 1120 is made of, but not limited to, at least one of the following materials: polymer, insulating dielectric and polysilicon. In this embodiment, the polymer includes, but is not limited to, at least one of benzocyclobutene (BCB), photosensitive epoxy resin photoresist (such as SU-8) and polyimide. In this embodiment, the insulating dielectric includes, but is not limited to, at least one of aluminum nitride, silicon dioxide, silicon nitride and titanium oxide. It should be noted that the thermal conductivity of the material of the intermediate layer 1120 is lower than that of the material of the substrate 1110.

In this embodiment, the thickness of the heat-dissipation layer 1140 is, but not limited to, 0.1 μm-5 μm. In this embodiment, the heat-dissipation layer 1140 is made of, but not limited to, at least one of the following materials: aluminum nitride, silicon carbide and diamond. It should be noted that the heat-dissipation layer 1140 is made of a material with the thermal conductivity better than that of the substrate 1110, thus compensating for the heat-dissipation performance of the resonance device.

In this embodiment, the electrode layer 1150 is made of, but not limited to, at least one of the following materials: molybdenum, ruthenium, tungsten, platinum, iridium, aluminum and beryllium. In this embodiment, cross-section A of the electrode layer 1150 is trapezoidal. In another embodiment, cross-section A of the lower electrode layer is rectangular.

In this embodiment, the piezoelectric layer 1160 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the protruding height h3 of the protruding part 1161 is equal to or greater than the thickness of the electrode layer 1150. In this embodiment, cross-section A of the protruding part 1161 is trapezoidal. In another embodiment, cross-section A of the first protruding part is rectangular.

In this embodiment, the electrode layer 1170 is made of, but not limited to, at least one of the following materials: molybdenum, ruthenium, tungsten, platinum, iridium, aluminum and beryllium.

In this embodiment, the protruding height h4 of the protruding part 1171 is equal to or greater than the thickness of the electrode layer 1150. In this embodiment, cross-section A of the protruding part 1171 is trapezoidal. In another embodiment, cross-section A of the second protruding part is rectangular.

FIG. 12 is a structural diagram of cross-section A of a BAW resonance device 1200 in an embodiment of the invention.

As shown in FIG. 12, an embodiment of the invention provides a BAW resonance device 1200 which comprises a substrate 1210, a heat-dissipation layer 1220, an electrode layer 1240, a piezoelectric layer 1250 and an electrode layer 1260, wherein the heat-dissipation layer 1220 is located on the substrate 1210 and has a first side 1221 and a second side 1222 opposite to the first side 1221, the substrate 1210 is located on the first side 1221, and the heat-dissipation layer 1220 further has a cavity 1230 located on the second side 1222; the electrode layer 1240 is located on the second side 1222, is disposed on the heat-dissipation layer 1220, and covers the cavity 1230; the piezoelectric layer 1250 is located on the second side 1222, is disposed on the heat-dissipation layer 1220, covers the electrode layer 1240, and comprises a protruding part 1251 located over the electrode layer 1240; the electrode layer 1260 is located on the second side 1222, is disposed on the piezoelectric layer 1250, and comprises a protruding part 1261 located over the protruding part 1251; and an overlap part of a resonance region (namely, an overlap region of the electrode layer 1240 and the electrode layer 1260) and the heat-dissipation layer 1220 is located on one side of the cavity 1230.

In this embodiment, the substrate 1210 is made of, but not limited to, at least one of the following materials: silicon, silicon carbide, glass, gallium arsenide and gallium nitride.

In this embodiment, the thickness of the heat-dissipation layer 1220 is, but not limited to, 0.1 μm-5 μm. In this embodiment, the heat-dissipation layer 1220 is made of, but not limited to, at least one of the following materials: aluminum nitride, silicon carbide and diamond. It should be noted that the heat-dissipation layer 1220 is made of a material with the thermal conductivity better than that of the substrate 1210, thus improving the heat-dissipation performance of the resonance device.

In this embodiment, the electrode layer 1240 is made of, but not limited to, at least one of the following materials: molybdenum, ruthenium, tungsten, platinum, iridium, aluminum and beryllium. In this embodiment, cross-section A of the electrode layer 1240 is trapezoidal. In another embodiment, cross-section A of the lower electrode layer is rectangular.

In this embodiment, the piezoelectric layer 1250 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the protruding height h5 of the protruding part 1251 is equal to or greater than the thickness of the electrode layer 1240. In this embodiment, cross-section A of the protruding part 1251 is trapezoidal. In another embodiment, cross-section A of the first protruding part is rectangular.

In this embodiment, the electrode layer 1260 is made of, but not limited to, at least one of the following materials: molybdenum, ruthenium, tungsten, platinum, iridium, aluminum and beryllium.

In this embodiment, the protruding height h6 of the protruding part 1261 is equal to or greater than the thickness of the electrode layer 1240. In this embodiment, cross-section A of the protruding part 1261 is trapezoidal. In another embodiment, cross-section A of the second protruding part is rectangular.

FIG. 13 is a structural diagram of cross-section A of a BAW resonance device 1300 in an embodiment of the invention.

As shown in FIG. 13, an embodiment of the invention provides a BAW resonance device 1300 which comprises a substrate 1310, an intermediate layer 1320, a heat-dissipation layer 1330, an electrode layer 1350, a piezoelectric layer 1360 and an electrode layer 1370, wherein the intermediate layer 1320 is located on the substrate 1310; the heat-dissipation layer 1330 is located on the intermediate layer 1320 and has a first side 1331 and a second side 1332 opposite to the first side 1331, the intermediate layer 1320 is located on the first side 1331, and the heat-dissipation layer 1330 further has a cavity 1340 located on the second side 1332; the electrode layer 1350 is located on the second side 1332, is disposed on the heat-dissipation layer 1330, and covers the cavity 1340; the piezoelectric layer 1360 is located on the second side 1332, is disposed on the heat-dissipation layer 1330, covers the electrode layer 1350, and comprises a protruding part 1361 located over the electrode layer 1350; the electrode layer 1370 is located on the second side 1320, is disposed on the piezoelectric layer 1360, and comprises a protruding part 1371 located over the protruding part 1361; and an overlap part of a resonance region (namely, an overlap region of the electrode layer 1350 and the electrode layer 1370) and the heat-dissipation layer 1330 is located on one side of the cavity 1340.

It should be noted that the acoustic impedance of the heat-dissipation layer 1330 is different from that of the intermediate layer 1320, so that the difference in acoustic impedance between the resonance region and a non-resonance region is increased to prevent acoustic waves generated in the resonance region from leaking into the non-resonance region.

In this embodiment, the substrate 1310 is made of, but not limited to, at least one of the following materials: silicon, silicon carbide, glass, gallium arsenide and gallium nitride.

In this embodiment, the thickness of the intermediate layer 1320 is, but not limited to, 0.1 μm-10 μm. In this embodiment, the intermediate layer 1320 is made of, but not limited to, at least one of the following materials: polymer, insulating dielectric and polysilicon. In this embodiment, the polymer includes, but is not limited to, at least one of benzocyclobutene (BCB), photosensitive epoxy resin photoresist (such as SU-8) and polyimide. In this embodiment, the insulating dielectric includes, but is not limited to, at least one of aluminum nitride, silicon dioxide, silicon nitride and titanium oxide. It should be noted that the thermal conductivity of the material of the intermediate layer 1320 is lower than that of the material of the substrate 1310.

In this embodiment, the thickness of the heat-dissipation layer 1330 is, but not limited to, 0.1 μm-5 μm. In this embodiment, the heat-dissipation layer 1330 is made of, but not limited to, at least one of the following materials: aluminum nitride, silicon carbide and diamond. It should be noted that the heat-dissipation layer 1330 is made of a material with the thermal conductivity better than that of the substrate 1310, thus compensating for the heat-dissipation performance of the resonance device.

In this embodiment, the electrode layer 1350 is made of, but not limited to, at least one of the following materials: molybdenum, ruthenium, tungsten, platinum, iridium, aluminum and beryllium. In this embodiment, cross-section A of the electrode layer 1350 is trapezoidal. In another embodiment, cross-section A of the lower electrode layer is rectangular.

In this embodiment, the piezoelectric layer 1360 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the protruding height h7 of the protruding part 1361 is equal to or greater than the thickness of the electrode layer 1350. In this embodiment, cross-section A of the protruding part 1361 is trapezoidal. In another embodiment, cross-section A of the first protruding part is rectangular.

In this embodiment, the electrode layer 1370 is made of, but not limited to, at least one of the following materials: molybdenum, ruthenium, tungsten, platinum, iridium, aluminum and beryllium.

In this embodiment, the protruding height h8 of the protruding part 1371 is equal to or greater than the thickness of the electrode layer 1350. In this embodiment, cross-section A of the protruding part 1371 is trapezoidal. In another embodiment, cross-section A of the second protruding part is rectangular.

FIG. 14 is a structural diagram of cross-section A of a BAW resonance device 1400 in an embodiment of the invention.

As shown in FIG. 14, an embodiment of the invention provides a BAW resonance device 1400 which comprises a substrate 1410, a heat-dissipation layer 1420, a reflection layer 1430, an electrode layer 1440, a piezoelectric layer 1450 and an electrode layer 1460, wherein the heat-dissipation layer 1420 is located on the substrate 1410 and has a first side 1421 and a second side 1422 opposite to the first side 1421, and the substrate 1410 is located on the first side 1421; the reflection layer 1430 is located on the second side 1422 and is disposed on the heat-dissipation layer 1420; the electrode layer 1440 is located on the second side 1422, is disposed on the heat-dissipation layer 1420, and comprises a protruding part 1441 located on the reflection layer 1430; the piezoelectric layer 1450 is located on the second side 1422, is disposed on the heat-dissipation layer 1420, covers the protruding part 1441, and comprises a protruding part 1451 located over the protruding part 1441; the electrode layer 1460 is located on the second side 1422, is disposed on the piezoelectric layer 1450, and comprises a protruding part 1461 located over the protruding part 1451; and a resonance region (namely, an overlap region of the electrode layer 1440 and the electrode layer 1460) is located over the reflection layer 1430.

In this embodiment, the substrate 1410 is made of, but not limited to, at least one of the following materials: silicon, silicon carbide, glass, gallium arsenide and gallium nitride.

In this embodiment, the heat-dissipation layer 1420 covers the substrate 1410. In this embodiment, the thickness of the heat-dissipation layer 1420 is, but not limited to, 0.1 μm-5 μm. In this embodiment, the heat-dissipation layer 1420 is made of, but not limited to, at least one of the following materials: aluminum nitride, silicon carbide and diamond. It should be noted that the heat-dissipation layer 1420 is made of a material with the thermal conductivity better than that of the substrate 1410, thus improving the heat-dissipation performance of the resonance device.

In this embodiment, the reflection layer 1430 is a cavity, and cross-section A of the cavity 1430 is trapezoidal. In another embodiment, cross-section A of the cavity is rectangular.

In this embodiment, the electrode layer 1440 is made of, but not limited to, at least one of the following materials: molybdenum, ruthenium, tungsten, platinum, iridium, aluminum and beryllium.

In this embodiment, the protruding height of the protruding part 1441 is equal to or greater than the depth of the cavity 1430. In this embodiment, cross-section A of the protruding part 1441 is trapezoidal. In another embodiment, cross-section A of the first protruding part is rectangular.

In this embodiment, the piezoelectric layer 1450 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the protruding height of the protruding part 1451 is equal to or greater than the depth of the cavity 1430. In this embodiment, cross-section A of the protruding part 1451 is trapezoidal. In another embodiment, cross-section A of the second protruding part is rectangular.

In this embodiment, the electrode layer 1460 is made of, but not limited to, at least one of the following materials: molybdenum, ruthenium, tungsten, platinum, iridium, aluminum and beryllium.

In this embodiment, the protruding height of the protruding part 1461 is equal to or greater than the depth of the cavity 1430. In this embodiment, cross-section A of the protruding part 1461 is trapezoidal. In another embodiment, cross-section A of the third protruding part is rectangular.

FIG. 15 is a structural diagram of cross-section A of a SAW resonance device 1500 in an embodiment of the invention.

As shown in FIG. 15, an embodiment of the invention provides a BAW resonance device 1500 which comprises a substrate 1510, an intermediate layer 1520, a heat-dissipation layer 1530, a reflection layer 1540, an electrode layer 1550, a piezoelectric layer 1560 and an electrode layer 1570, wherein the intermediate layer 1520 is located on the substrate 1510; the heat-dissipation layer 1530 is located on the intermediate layer 1520 and has a first side 1531 and a second side 1532 opposite to the first side 1531, and the intermediate layer 1520 is located on the first side 1531; the reflection layer 1540 is located on the second side 1531 and is disposed on the heat-dissipation layer 1530; the electrode layer 1550 is located on the second side 1532, is disposed on the heat-dissipation layer 1530, and comprises a protruding part 1551 located on the reflection layer 1540; the piezoelectric layer 1560 is located on the second side 1532, is disposed on the heat-dissipation layer 1530, covers the protruding part 1551, and comprises a protruding part 1561 located over the protruding part 1551; the electrode layer 1570 is located on the second side 1532, is disposed on the piezoelectric layer 1560, and comprises a protruding part 1571 located over the protruding part 1561; and a resonance region (namely, an overlap region of the electrode layer 1550 and the electrode layer 1570) is located over the reflection layer 1540.

It should be noted that the acoustic impedance of the heat-dissipation layer 1530 is different from that of the intermediate layer 1520, so that the difference in acoustic impedance between the resonance region and a non-resonance region can be increased to prevent acoustic waves generated in the resonance region from leaking into the non-resonance region.

In this embodiment, the substrate 1510 is made of, but not limited to, at least one of the following materials: silicon, silicon carbide, glass, gallium arsenide and gallium nitride.

In this embodiment, the thickness of the intermediate layer 1520 is, but not limited to, 0.1 μm-10 μm. In this embodiment, the intermediate layer 1520 is made of, but not limited to, at least one of the following materials: polymer, insulating dielectric and polysilicon. In this embodiment, the polymer includes, but is not limited to, at least one of benzocyclobutene (BCB), photosensitive epoxy resin photoresist (such as SU-8) and polyimide. In this embodiment, the insulating dielectric includes, but is not limited to, at least one of aluminum nitride, silicon dioxide, silicon nitride and titanium oxide. It should be noted that the thermal conductivity of the material of the intermediate layer 1520 is lower than that of the material of the substrate 1510.

In this embodiment, the heat-dissipation layer 1530 covers the intermediate layer 1520. In this embodiment, the thickness of the heat-dissipation layer 1530 is, but not limited to, 0.1 μm-5 μm. In this embodiment, the heat-dissipation layer 1530 is made of, but not limited to, at least one of the following materials: aluminum nitride, silicon carbide and diamond. It should be noted that the heat-dissipation layer 1530 is made of a material with the thermal conductivity better than that of the substrate 1510, thus compensating for the heat-dissipation performance of the resonance device.

In this embodiment, the reflection layer 1540 is a cavity, and cross-section A of the cavity 1540 is trapezoidal. In another embodiment, cross-section A of the cavity is rectangular.

In this embodiment, the electrode layer 1550 is made of, but not limited to, at least one of the following materials: molybdenum, ruthenium, tungsten, platinum, iridium, aluminum and beryllium.

In this embodiment, the protruding height of the protruding part 1551 is equal to or greater than the depth of the cavity 1540. In this embodiment, cross-section A of the protruding part 1551 is trapezoidal. In another embodiment, cross-section A of the first protruding part is rectangular.

In this embodiment, the piezoelectric layer 1560 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the protruding height of the protruding part 1561 is equal to or greater than the depth of the cavity 1540. In this embodiment, cross-section A of the protruding part 1561 is trapezoidal. In another embodiment, cross-section A of the second protruding part is rectangular.

In this embodiment, the electrode layer 1570 is made of, but not limited to, at least one of the following materials: molybdenum, ruthenium, tungsten, platinum, iridium, aluminum and beryllium.

In this embodiment, the protruding height of the protruding part 1571 is equal to or greater than the depth of the cavity 1540. In this embodiment, cross-section A of the protruding part 1571 is trapezoidal. In another embodiment, cross-section A of the third protruding part is rectangular.

FIG. 16 is a structural diagram of cross-section A of a SAW resonance device 1600 in an embodiment of the invention.

As shown in FIG. 16, an embodiment of the invention provides a SAW resonance device 1600 which comprises a substrate 1610, a heat-dissipation layer 1620, a reflection layer 1630, an electrode layer 1640, a piezoelectric layer 1650 and an electrode layer 1660, wherein the heat-dissipation layer 1620 is located on the substrate 1610 and has a first side 1621 and a second side 1622 opposite to the first side 1621, and the substrate 1610 is located on the first side 1621; the reflection layer 1630 is located on the second side 1622 and is disposed on the heat-dissipation layer 1620; the electrode layer 1640 is located on the second side 1622, is disposed on the heat-dissipation layer 1620, and comprises a protruding part 1641 located on the reflection layer 1630; the piezoelectric layer 1650 is located on the second side 1622, is disposed on the heat-dissipation layer 1620, covers the protruding part 1641, and comprises a protruding part 1651 located over the protruding part 1641; the electrode layer 1660 is located on the second side 1622, is disposed on the piezoelectric layer 1650, and comprises a protruding part 1661 located over the protruding part 1651; and a resonance region (namely, an overlap region of the electrode layer 1640 and the electrode layer 1660) is located over the reflection layer 1630.

In this embodiment, the substrate 1610 is made of, but not limited to, at least one of the following materials: silicon, silicon carbide, glass, gallium arsenide and gallium nitride.

In this embodiment, the heat-dissipation layer 1620 covers the substrate 1610. In this embodiment, the thickness of the heat-dissipation layer 1620 is, but not limited to, 0.1 μm-5 μm. In this embodiment, the heat-dissipation layer 1620 is made of, but not limited to, at least one of the following materials: aluminum nitride, silicon carbide and diamond. It should be noted that the heat-dissipation layer 1620 is made of a material with the thermal conductivity better than that of the substrate 1610, thus improving the heat-dissipation performance of the resonance device.

In this embodiment, the reflection layer 1630 is a cavity, and cross-section A of the cavity 1630 is arched.

In this embodiment, the electrode layer 1640 is made of, but not limited to, at least one of the following materials: molybdenum, ruthenium, tungsten, platinum, iridium, aluminum and beryllium.

In this embodiment, the protruding height of the protruding part 1641 is equal to or greater than the depth of the cavity 1630. In this embodiment, cross-section A of the protruding part 1441 is arched.

In this embodiment, the piezoelectric layer 1650 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the protruding height of the protruding part 1651 is equal to or greater than the depth of the cavity 1630. In this embodiment, cross-section A of the protruding part 1651 is arched.

In this embodiment, the electrode layer 1660 is made of, but not limited to, at least one of the following materials: molybdenum, ruthenium, tungsten, platinum, iridium, aluminum and beryllium.

In this embodiment, the protruding height of the protruding part 1661 is equal to or greater than the depth of the cavity 1630. In this embodiment, cross-section A of the protruding part 1661 is arched.

FIG. 17 is a structural diagram of cross-section A of a BAW resonance device 1700 in an embodiment of the invention.

As shown in FIG. 17, an embodiment of the invention provides a BAW resonance device 1700 which comprises a substrate 1710, an intermediate layer 1720, a heat-dissipation layer 1730, a reflection layer 1740, an electrode layer 1750, a piezoelectric layer 1760 and an electrode layer 1770, wherein the intermediate layer 1720 is located on the substrate 1710; the heat-dissipation layer 1730 is located on the intermediate layer 1720 and has a first side 1731 and a second side 1732 opposite to the first side 1731, and the intermediate layer 1720 is located on the first side 1731; the reflection layer 1740 is located on the second side 1732 and is disposed on the heat-dissipation layer 1730; the electrode layer 1750 is located on the second side 1732, is disposed on the heat-dissipation layer 1730, and comprises a protruding part 1751 located on the reflection layer 1740; the piezoelectric layer 1760 is located on the second side 1732, is disposed on the heat-dissipation layer 1730, covers the protruding part 1751, and comprises a protruding part 1761 located over the protruding part 1751; the electrode layer 1770 is located on the second side 1732, is disposed on the piezoelectric layer 1760, and comprises a protruding part 1771 located over the protruding part 1761; and a resonance region (namely, an overlap region of the electrode layer 1750 and the electrode region 1770) is located over the reflection layer 1740.

It should be noted that the acoustic impedance of the heat-dissipation layer 1730 is different from that of the intermediate layer 1720, so that the difference in acoustic impedance between the resonance region and a non-resonance region can be increased to prevent acoustic waves generated in the resonance region from leaking into the non-resonance region.

In this embodiment, the substrate 1710 is made of, but not limited to, at least one of the following materials: silicon, silicon carbide, glass, gallium arsenide and gallium nitride.

In this embodiment, the thickness of the intermediate layer 1720 is, but not limited to, 0.1 μm-10 μm. In this embodiment, the intermediate layer 1720 is made of, but not limited to, at least one of the following materials: polymer, insulating dielectric and polysilicon. In this embodiment, the polymer includes, but is not limited to, at least one of benzocyclobutene (BCB), photosensitive epoxy resin photoresist (such as SU-8) and polyimide. In this embodiment, the insulating dielectric includes, but is not limited to, at least one of aluminum nitride, silicon dioxide, silicon nitride and titanium oxide. It should be noted that the thermal conductivity of the material of the intermediate layer 1720 is lower than that of the material of the substrate 1710.

In this embodiment, the heat-dissipation layer 1730 covers the intermediate layer 1720. In this embodiment, the thickness of the heat-dissipation layer 1730 is, but not limited to, 0.1 μm-5 μm. In this embodiment, the heat-dissipation layer 1730 is made of, but not limited to, at least one of the following materials: aluminum nitride, silicon carbide and diamond. It should be noted that the heat-dissipation layer 1730 is made of a material with the thermal conductivity better than that of the substrate 1710, thus compensating for the heat-dissipation performance of the resonance device.

In this embodiment, the reflection layer 1740 is a cavity, and cross-section A of the cavity 1740 is arched.

In this embodiment, the electrode layer 1750 is made of, but not limited to, at least one of the following materials: molybdenum, ruthenium, tungsten, platinum, iridium, aluminum and beryllium.

In this embodiment, the protruding height of the protruding part 1751 is equal to or greater than the depth of the cavity 1740. In this embodiment, cross-section A of the protruding part 1751 is arched.

In this embodiment, the piezoelectric layer 1760 is made of, but not limited to, at least one of the following materials: aluminum nitride, aluminum oxide alloy, gallium nitride, zinc oxide, lithium tantalate, lithium niobate, lead zirconate titanate and PMN-PT.

In this embodiment, the protruding height of the protruding part 1761 is equal to or greater than the depth of the cavity 1740. In this embodiment, cross-section A of the protruding part 1761 is arched.

In this embodiment, the electrode layer 1770 is made of, but not limited to, at least one of the following materials: molybdenum, ruthenium, tungsten, platinum, iridium, aluminum and beryllium.

In this embodiment, the protruding height of the protruding part 1771 is equal to or greater than the depth of the cavity 1740. In this embodiment, cross-section A of the protruding part 1771 is arched.

An embodiment of the invention further provides a filter device which comprises, but is not limited to, at least one BAW resonance device provided by one of the aforementioned embodiments.

An embodiment of the invention further provides an RF front-end device which comprises, but is not limited to, at least one filter device provided by the aforementioned embodiment, and a power amplification device connected to the filter device.

An embodiment of the invention further provides an RF front-end device which comprises, but is not limited to, at least one filter device provided by the aforementioned embodiment, and a low-noise amplification device connected to the filter device.

An embodiment of the invention further provides an RF front-end device which comprises, but is not limited to, a multiplexing device, wherein the multiplexing device comprises at least one filter device provided by the aforementioned embodiment.

To sum up, the BAW resonance device comprises the heat-dissipation layer, which is located on the substrate or the intermediate layer and can improve or flexibly adjust the heat-dissipation performance of the BAW resonance device (for example, the heat-dissipation layer can increase the Q value of the BAW resonance device and compensate for the heat-dissipation performance of the BAW resonance device).

It should be understood that the examples and embodiments in this specification are merely illustrative ones, and various modifications and amendments can be made by those skilled in the art without departing from the spirit and scope defined by this application and the appended claims.

1. A BAW resonance device, comprising:
a first passive part comprising a first substrate and a first heat-dissipation layer located over the first substrate;
a first active part comprising a first piezoelectric layer, a first electrode layer and a second electrode layer, wherein the first piezoelectric layer is located over the first passive part and has a first side and a second side opposite to the first side, the first passive part is located on the first side, the first electrode layer is also located on the first side and is disposed between the first passive part and the first piezoelectric layer, and the second electrode layer is located on the second side; and
a first cavity located on the first side and disposed between the first passive part and the first piezoelectric layer, wherein at least one part of the first electrode layer is located on or in the first cavity.

2. The BAW resonance device according to claim 1, wherein the first heat-dissipation layer is made of at least one of the following materials: aluminum nitride, silicon carbide and diamond.

3. The BAW resonance device according to claim 1, wherein a thickness of the first heat-dissipation layer is 0.1 μm-5 μm.

4. The BAW resonance device according to claim 1, wherein the first cavity is inlaid in the first passive part and is located between the first substrate and the first piezoelectric layer, and the first heat-dissipation layer is located on two sides of the first cavity.

5. The BAW resonance device according to claim 1, wherein the first cavity is inlaid in the first passive part and is located between the first heat-dissipation layer and the first piezoelectric layer, and the first heat-dissipation layer is located on two sides of the first cavity.

6. The BAW resonance device according to claim 1, wherein the first electrode layer is located in the first cavity, and the first piezoelectric layer is located on the first electrode layer.

7. The BAW resonance device according to claim 1, wherein the first heat-dissipation layer has a first groove; the first electrode layer has a first end and a second end opposite to the first end, the first end is located in the first cavity, and the second end is located in the first groove; and the first piezoelectric layer is located on the first electrode layer.

8. The BAW resonance device according to claim 1, wherein the first cavity is inlaid in the first passive part and is located between the first substrate and the first electrode layer, and the first heat-dissipation layer is located on two sides of the first cavity.

9. The BAW resonance device according to claim 1, wherein the first cavity is inlaid in the first passive part and is located between the first heat-dissipation layer and the first electrode layer, and the first heat-dissipation layer is located on two sides of the first cavity.

10. The BAW resonance device according to claim 1, wherein the first electrode layer is located on the first cavity and is covered with the first piezoelectric layer.

11. The BAW resonance device according to claim 10, wherein the first piezoelectric layer comprises a first protruding part located over the first electrode layer, and the second electrode layer is located on the first piezoelectric layer and comprises a second protruding part located over the first protruding part.

12. The BAW resonance device according to claim 11, wherein the first protruding part is of at least one of the following shapes: trapezoidal shape and rectangular shape; and the second protruding part is of at least one of the following shapes: trapezoidal shape and rectangular shape.

13. The BAW resonance device according to claim 1, wherein the first cavity is located between the first heat-dissipation layer and the first piezoelectric layer and is disposed on the first heat-dissipation layer.

14. The BAW resonance device according to claim 13, wherein the first electrode layer is located on the first heat-dissipation layer and comprises a third protruding part located on the first cavity, the first piezoelectric layer covers the first cavity and comprises a fourth protruding part located over the third protruding part, and the second electrode layer is located on the first piezoelectric layer and comprises a fifth protruding part located over the fourth protruding part.

15. The BAW resonance device according to claim 14, wherein the third protruding part is of at least one of the following shapes: trapezoidal shape, arch shape and rectangular shape; the fourth protruding part is of at least one of the following shapes: trapezoidal shape, arch shape and rectangular shape; and the fifth protruding part is of at least one of the following shapes: trapezoidal shape, arch shape and rectangular shape.

16. The BAW resonance device according to claim 1, wherein the first passive part further comprises a first intermediate layer located between the first substrate and the first heat-dissipation layer and disposed on the first substrate, and the first heat-dissipation layer is located on the first intermediate layer.

17. The BAW resonance device according to claim 16, wherein the first intermediate layer is made of at least one of the following materials: polymer, insulating dielectric and polysilicon.

18. The BAW resonance device according to claim 16, wherein a thickness of the first intermediate layer is 0.1 μm-10 μm.

19. The BAW resonance device according to claim 16, wherein the first cavity is inlaid in the first passive part and is located between the first intermediate layer and the first piezoelectric layer, and the first heat-dissipation layer is located on two sides of the first cavity.

20. The BAW resonance device according to claim 16, wherein the first electrode layer is located in the first cavity, and the first piezoelectric layer is located on the first electrode layer.

21. The BAW resonance device according to claim 16, wherein the first heat-dissipation layer has a second groove; the first electrode layer has a third end and a fourth end opposite to the third end, the third end is located in the first cavity, and the fourth end is located in the second groove; and the first piezoelectric layer is located on the first electrode layer.

22. The BAW resonance device according to claim 16, wherein the first cavity is inlaid in the first passive part and is located between the first intermediate layer and the first electrode layer, and the first heat-dissipation layer is located on two sides of the first cavity.

23. The BAW resonance device according to claim 16, wherein the first electrode layer is located on the first cavity and is covered with the first piezoelectric layer.

24. The BAW resonance device according to claim 23, wherein the first piezoelectric layer comprises a sixth protruding part located over the first electrode layer, and the second electrode layer is located on the first piezoelectric layer and comprises a seventh protruding part located on the sixth protruding part.

25. The BAW resonance device according to claim 24, wherein the sixth protruding part is of at least one of the following shapes: trapezoidal shape and rectangular shape; and the seventh protruding part is of at least one of the following shapes: trapezoidal shape and rectangular shape.

26. A filter device, comprising at least one BAW resonance device according to any one of claims 1-25.

27. An RF front-end device, comprising a power amplification device and at least one filter device according to claim 26, wherein the power amplification device is connected to the filter device.

28. An RF front-end device, comprising a low-noise amplification device and at least one filter device according to claim 26, wherein the low-noise amplification device is connected to the filter device.

29. An RF front-end device, comprising a multiplexing device, wherein the multiplexing device comprises at least one filter device according to claim 26.
